(19) United States
(12) Patent Application Publication
(10) Pub. No.: US 2012/0138891 A1
(43) Pub. Date: Jun. 7, 2012

(54) METHOD FOR REDUCTION OF EFFICIENCY DROOP USING AN (Al,In,Ga)N/Al(x)In(1-x)N SUPERLATTICE ELECTRON BLOCKING LAYER IN NITRIDE BASED LIGHT EMITTING DIODES

(75) Inventors: Roy B. Chung, Carlsbad, CA (US); Changseok Han, Gyeonggi-do (KR); Steven P. DenBaars, Goleta, CA (US); James S. Speck, Goleta, CA (US); Shuji Nakamura, Santa Barbara, CA (US)

(73) Assignee: THE REGENTS OF THE UNIVERSITY OF CALIFORNIA, Oakland, CA (US)

(21) Appl. No.: 13/282,794

(22) Filed: Oct. 27, 2011

Related U.S. Application Data
(60) Provisional application No. 61/407,362, filed on Oct. 27, 2010.

(51) Int. Cl. H01L 33/04

(52) U.S. Cl. 257/13; 438/47; 257/15; 257/E33.007

(57) ABSTRACT

A method for reduction of efficiency droop using an (Al, In, Ga)N/AlₓIn₁₋ₓN superlattice electron blocking layer (SL-EBL) in nitride based light emitting diodes.

### CROSS REFERENCE TO RELATED APPLICATION

This application claims the benefit under 35 U.S.C. Section 119(e) of the following co-pending and commonly-assigned application:

U.S. Provisional Patent Application Ser. No. 61/407,362, filed on Oct. 27, 2010, by Roy B. Chung, Changseok Han, Steven P. DenBaars, James S. Speck, and Shuji Nakamura, entitled “METHOD FOR REDUCTION OF EFFICIENCY DROOP USING AN (Al,In,Ga)N/Al(x)In(1−x)N SUPERLATTICE ELECTRON BLOCKING LAYER IN NITRIDE BASED LIGHT EMITTING DIODES,” attorneys' docket number 30794.399-US-P1 (2011-230-1);

which application is incorporated by reference herein.

This application is related to the following co-pending and commonly-assigned applications:

U.S. Utility patent application Ser. No. ______, filed on Oct. 27, 2011, by Shuji Nakamura, Steven P. DenBaars, Shinichi Tanaka, Junichi Sonoda, Hung Tse Chen, and Chih-Chien Pan, entitled “LIGHT EMITTING DIODE FOR DROOP IMPROVEMENT,” attorneys' docket number 30794.394-US-U1 (2011-169-2), which application claims the benefit under 35 U.S.C. Section 119(e) of co-pending and commonly-assigned U.S. Provisional Patent Application Ser. No. 61/407,343, filed on Oct. 27, 2010, by Shuji Nakamura, Steven P. DenBaars, Shinichi Tanaka, Junichi Sonoda, Hung Tse Chen, and Chih-Chien Pan, entitled “LIGHT EMITTING DIODE FOR DROOP IMPROVEMENT,” attorneys' docket number 30794.394-US-P1 (2011-169-1);

U.S. Utility patent application Ser. No. ______, filed on Oct. 27, 2011, by Yuji Zhao, Junichi Sonoda, Chih-Chien Pan, Shinichi Tanaka, Steven P. DenBaars, and Shuji Nakamura, entitled “HIGH POWER, HIGH EFFICIENCY AND LOW EFFICIENCY DROOP III-NITRIDE LIGHT-EMITTING DIODES ON SEMIPOLAR {20-2-1} SUBSTRATES,” attorneys' docket number 30794.403-US-U1 (2011-258-2), which application claims the benefit under 35 U.S.C. Section 119(e) of co-pending and commonly-assigned U.S. Provisional Patent Application Ser. No. 61/407,357, filed on Oct. 27, 2010, by Yuji Zhao, Junichi Sonoda, Chih-Chien Pan, Shinichi Tanaka, Steven P. DenBaars, and Shuji Nakamura, entitled “HIGH POWER, HIGH EFFICIENCY AND LOW EFFICIENCY DROOP III-NITRIDE LIGHT-EMITTING DIODES ON SEMIPOLAR {20-2-1} SUBSTRATES,” attorneys' docket number 30794.403-US-P1 (2011-258-1);

U.S. Provisional Patent Application Ser. No. 61/495,829, filed on Jun. 10, 2011, by Shuji Nakamura, Steven P. DenBaars, Shinichi Tanaka, Daniel F. Feezell, Yuji Zhao, and Chih-Chien Pan, entitled “LOW DROOP LIGHT EMITTING DIODE STRUCTURE ON GALLIUM NITRIDE SEMIPOLAR {20-2-1} SUBSTRATES,” attorneys' docket number 30794.415-US-P1 (2011-832-1);

U.S. Provisional Patent Application Ser. No. 61/495,840, filed on Jun. 10, 2011, by Shuji Nakamura, Steven P. DenBaars, Daniel F. Feezell, Chih-Chien Pan, Yuji Zhao, and Shinichi Tanaka, entitled “HIGH EMISSION POWER AND LOW EFFICIENCY DROOP SEMIPOLAR {20-2-1} BLUE LIGHT EMITTING DIODES,” attorneys' docket number 30794.416-US-P1 (2011-833-1);

all of which applications are incorporated by reference herein.

### BACKGROUND OF THE INVENTION

1. Field of the Invention

The invention is related to the field of light emitting diodes (LEDs).

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Nitride-based LEDs have been extensively studied since the first demonstration of high efficiency and high power blue LEDs by Nakamura et al. [1] Although both the internal quantum efficiency and the extraction efficiency have improved dramatically since then, there seems to be a physical limitation that prevents these LEDs from reaching their maximum efficiency.

Besides the lack of a native GaN substrate and other growth issues, one of the major challenges for achieving high brightness nitride LEDs is efficiency droop, which is a phenomenon that describes the decrease in the external quantum efficiency (EQE) with increasing injection current. [2] Although the origin of efficiency droop is not yet fully understood, several physical processes, such as carrier leakage and Auger recombination, have been suggested as major causes.

To minimize carrier leakage, a typical nitride LED structure includes an AlGaN electron blocking layer (EBL) layer above the active region and below the p-type cladding layer. This is illustrated in the schematic diagram of FIG. 1(a), which shows a c-plane LED fabricated on a sapphire substrate 100, wherein the LED is comprised of an n-type GaN cladding layer 102, an active region comprised of an InGaN/(In)GaN multiple quantum well (MQW) structure 104, an AlGaN:Mg EBL 106, a p-type GaN cladding layer 108, and a p+GaN layer 110.

The EBL has a larger bandgap than the active region, thereby creating a barrier in a conduction band for electrons injected from the n-type GaN cladding layer and preventing these electrons from overflowing into the p-type GaN cladding layer. Schematic conduction band (CB) and valence band (VB) diagrams for the device of FIG. 1(a) are shown in FIG. 1(b), illustrating a barrier 112, a last well 114, a barrier 116 and an AlGaN EBL 118.

However, tensile strain in AlGaN, due to the smaller lattice constant, limits its composition and thickness. Low composition means a lower barrier, and high composition means a thinner EBL, in order to avoid cracking. Furthermore, the growth temperature is also limited due to the low temperature growth of the active region.

One method to circumvent these disadvantages with AlGaN is to replace it with AlₓIn₁₋ₓN. [3] The advantage of AlₓIn₁₋ₓN is that it can be lattice matched to GaN while maintaining a bandgap of ˜4.2 eV. [4] For the same bandgap energy, AlGaN requires ˜45% Al, which would crack if the thickness were more than only few nanometers. Furthermore, the conduction band offset with respect to GaN is expected to be very large, creating a large barrier for electrons. [5]

However, successful growth of p-type thick AlInN has not been reported and high oxygen concentration seems to create high concentration of electrons (1×10¹⁸ cm⁻³) in undoped AlInN. Compensating these many electrons with Mg doping could start compromising the crystal quality. [6]

Thus, there is a need in the art for LEDs where the efficiency droop problem has been resolved. The present invention satisfies this need.

### SUMMARY OF THE INVENTION

To overcome the limitations in the prior art described above, and to overcome other limitations that will become apparent upon reading and understanding the present specification, the present invention discloses a method for reduction of efficiency droop using an (Al, In, Ga)N/AlₓIn₁₋ₓN superlattice electron blocking layer (SL-EBL) in nitride based light emitting diodes.

### BRIEF DESCRIPTION OF THE DRAWINGS

Referring now to the drawings in which like reference numbers represent corresponding parts throughout:

FIG. 1(a) is a schematic diagram of a c-plane LED structure on a c-plane sapphire substrate, and FIG. 1(b) is a band diagram for a well, barrier and electron blocking layer (EBL) in the device of FIG. 1(a).

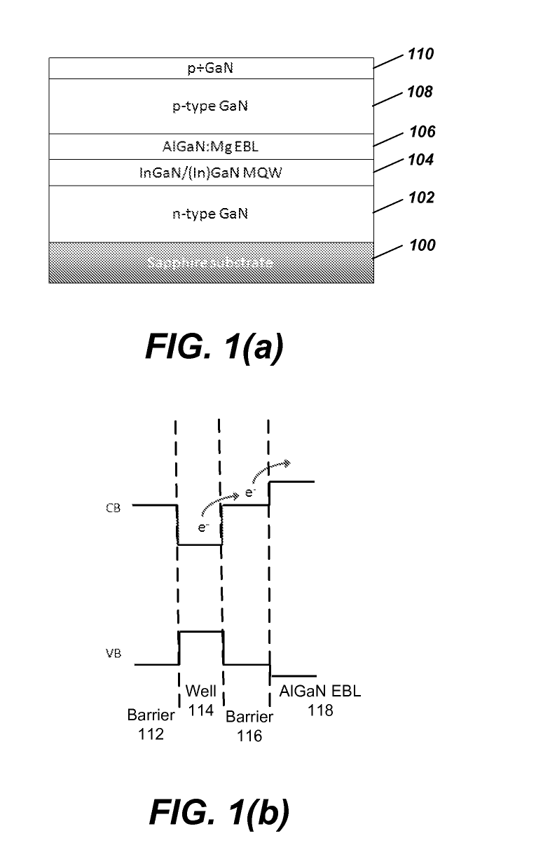

FIG. 2 is a flowchart that describes a method for fabricating a superlattice electron blocking layer (SL-EBL) according to a preferred embodiment of the present invention.

FIG. 3 is a schematic diagram of a c-plane LED structure resulting from the fabrication steps of FIG. 2.

FIG. 4(a) is a graph illustrating the normalized EQE as a function of driving current and FIG. 4(b) is a graph illustrating the I-V characteristics, for AlGaN EBL LEDs and AlInN/GaN SL-EBL LEDs.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention describes an optoelectronic device having a superlattice electron blocking layer (SL-EBL), wherein the SL-EBL is comprised of two or more groups of alternating AlₓIn₁₋ₓN and (Al, In)GaN layers, with the thickness of each layer being between about 1 nm and about 5 nm. The SL-EBL is grown near, e.g., on or above or proximate to, the active region of the device and can reduce efficiency droop, especially at high injection current conditions, as compared to devices without the SL-EBL. Operating voltage is also comparable to LEDs with an AlGaN EBL, suggesting that Mg doping in the SL-EBL is at least as efficient as Mg doping in a single thick (approximately 20 nm) AlGaN layer.

Longer wavelength LEDs are known to have larger efficiency droop, and the SL-EBL can be applied to those LEDs to reduce efficiency droop. Compared to a conventional AlGaN EBL, the efficiency droop is about 5˜10% less from its peak external quantum efficiency for an AlInN/GaN SL-EBL. Thus, using the present invention, blue LEDs can be provided with a lower efficiency droop, which directly relates to the cost of operation of a LED, especially under high injection current.

LEDs with AlInN:Mg/GaN:Mg SL-EBL have been successfully grown on a c-plane sapphire and fabricated. Packaged LEDs that are similar to existing commercial LEDs have demonstrated lower efficiency droop.

The light output power is still lower and the operating voltage is slightly higher than existing commercial LEDs. Thus, further optimization of the active region and p-type GaN is still needed.

Technical Description

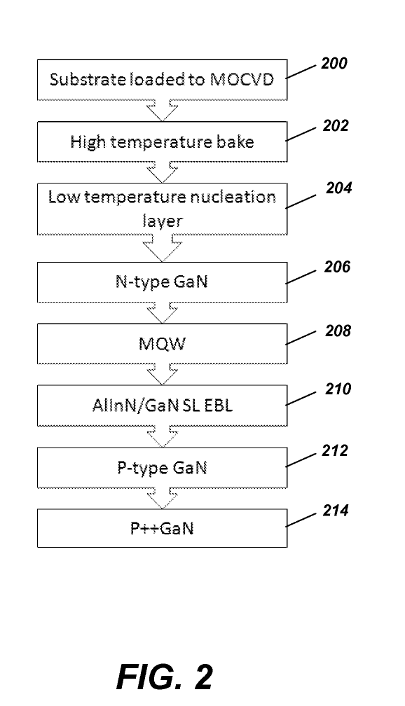

The present invention describes an SL-EBL comprised of at least two groups of AlₓIn₁₋ₓN and (Al,In)GaN layers, wherein each layer's thickness is between about 1 nm and about 5 nm. The present invention also describes a method for fabricating the SL-EBL, which is illustrated in the flow chart of FIG. 2.

Block 200 represents a c-plane sapphire being loaded into a metal organic chemical vapor deposition (MOCVD) reactor.

Block 202 represents a high temperature bake being performed, wherein the substrate is heated up above 1000° C. for surface treatment.

After the treatment, Block 204 represents the temperature being lowered to 520° C. and trimethylgallium (TMGa) and ammonia (NH₃) being introduced to grow a low temperature GaN nucleation layer.

Block 206 represents the growth temperature being ramped up above 1000° C. to grow an n-type GaN layer, wherein a thickness of about 1.5 μm of high temperature GaN is grown, and another 1.5 μm thickness of Si doped GaN (i.e., n-type GaN) is grown.

After the growth of the n-type GaN, Block 208 represents the temperature being lowered below 800° C. to grow an active region having an InGaN-based MQW structure. In this block, a low In composition InGaN barrier is grown with trimethylindium (TMIn), triethylgallium (TEGa), and NH₃. Then, the TMIn flow is increased to grow a well with a higher In composition, followed by another barrier identical to the first barrier layer. These steps may be repeated, for example, 6 times to make a 6 well MQW.

Block 210 represents the fabrication of the AlInN/GaN SL-EBL. After the last barrier of the MQW is grown, the TMGa flow is halted and trimethylaluminum (TMAl) is introduced to the reactor. The TMIn flow is also adjusted to achieve the composition that will make the lattice constant of AlInN close to the underlying epitaxial layers. The growth temperature for AlInN is 780° C. to 810° C. This layer is doped with Mg to create a p-type layer. After growing a thickness between 1 and 5 nm, the TMIn and TMAl flows are halted and GaN is grown with TEGa, until it is about the same thickness as the AlInN. These two layers are then repeated at least two times to form a superlattice structure comprising the SL-EBL.

After the growth of the last period of the superlattice structure, Block 212 represents the temperature being ramped up above 900° C. and a high temperature p-type GaN layer being grown (via Mg doping).

Finally, Block 214 represents, as a last layer, a higher Mg doped (p++) GaN layer being grown as a contact layer to reduce the contact resistance as much as possible.

The following steps are not shown in FIG. 2, but may also be performed. After the fabrication of an LED with the AlInN/GaN SL-EBL, the sample is taken out of a reactor and activated in a furnace for 15 minutes. The annealing temperature is above 600° C. and annealing is done under an N₂/O₂ ambient. After the activation, a transparent conducting oxide (TCO) layer, such as tin-doped indium oxide, is deposited as a p-type electrode, followed by mesa patterning using a photoresist. The mesa is formed by a dry-etching technique. The TCO layer is then annealed to increase its transparency and conductivity. After the annealing, an n-type electrode, such as Ti/Al/Ni/Au, is deposited on the n-type GaN layer, which is exposed by a dry etching technique. Then, Ti/Au is deposited for the wire bonding pads on both the n-type and p-type GaN layers. Metal contacts are then also annealed in an N₂ ambient for 5 minutes. The annealing temperature is between 300° C. and 600° C. Each LED chip on the wafer is then diced into a single device and mounted on a silver header. After wire bonding, the top of the silver header is encapsulated with Si forming a dome shape encapsulation, which enhances the light extraction. The packaged device is then placed inside an integrated sphere and the output power is measured at different injection current level.

It has been determined, through experimental results, that this invention works best for nitride-based LEDs with a peak emission wavelength longer than 370 nm. Also, the LEDs shown in this invention were grown by MOCVD, but this structure can also be grown by molecular beam epitaxy (MBE).

Resulting Device Structure

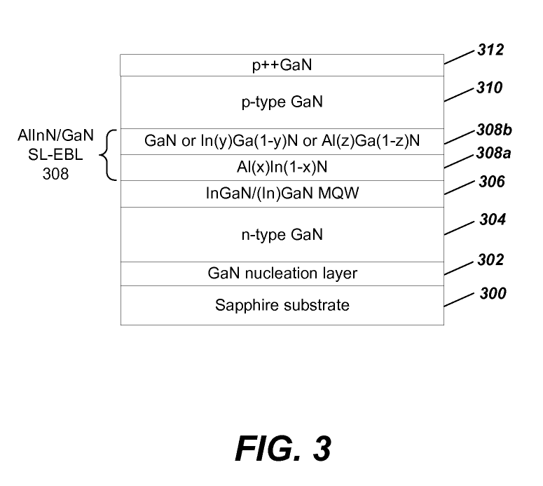

FIG. 3 is a schematic diagram of a c-plane LED resulting from the fabrication steps of FIG. 2, wherein the LED is comprised of a c-plane sapphire 300, a low temperature GaN nucleation layer 302, an n-type GaN layer 304, an active region 306 for emitting light having an InGaN-based MQW structure, an AlInN/GaN SL-EBL 308, a p-type GaN layer 310, and a p++ GaN contact layer 312.

The AlInN/GaN SL-EBL 308 preferably has a first layer 308a including at least Al and In; and a second layer including at least Ga 308b, wherein the first layer 308a is closely lattice matched to the second layer 308b and the first layer 308a is closely lattice matched to an underlying epitaxial layer, namely the active region 306. Preferably, the first layer 308a is AlₓIn₁₋ₓN and the second layer 308b is GaN, In_{y}Ga_{1-y}N, or Al_{z}Ga_{1-z}N. More preferably, the first layer 308a may comprise AlₓIn₁₋ₓN where 0.77≦x≦0.85. In addition, the first layer 308a and/or second layer 308b may be Mg doped to create p-type layers.

In one embodiment, the first layer 308a has a thickness of about 1 nm to about 5 nm, and the second layer 308b has a thickness of about 1 nm to about 5 nm. The first and second layers 308a, 308b are repeated at least two times to form the superlattice structure, and may be repeated enough times to form a superlattice structure have a thickness of about 20 nm to about 50 nm.

It has been determined that an optoelectronic device incorporating the AlInN/GaN SL-EBL 308 of the present invention has a reduced droop as compared to an optoelectronic device without a III-nitride SL-EBL.

Possible Modifications and Variations

This invention can be applied to nitride LEDs grown on a different crystallographic plane substrate such as a nonpolar m-plane and a-plane and other semi-polar planes. Also, because the lattice constant of AlInN can be lattice-matched to underlying layers while maintaining larger bandgap, this invention can be applied to longer wavelength LEDs, such as green, yellow, and red LEDs.

Advantages and Improvements

AlGaN has been the most common ternary alloy used as an EBL in nitride LEDs. However, Al composition is limited due to the tensile strain in AlGaN grown on GaN or InGaN layers. Due to this intrinsic material issue, AlGaN can only be grown in low Al composition and thicker (˜20 nm) layers, or in high Al composition and thinner layers. For these reasons, AlInN is the most suitable layer as an EBL, but it is difficult to achieve thick p-type AlInN layers due to the high concentration of impurities that are donor-like. [7]

The present invention avoids these issues by growing thin p-AlInN and thin p-GaN layers, and then repeating these layers several times to achieve an effective thickness as high as a single AlInN EBL, but with possibly higher hole concentration. Furthermore, this technique can be applied to longer wavelength LEDs in which the efficiency droop has shown to be even larger.

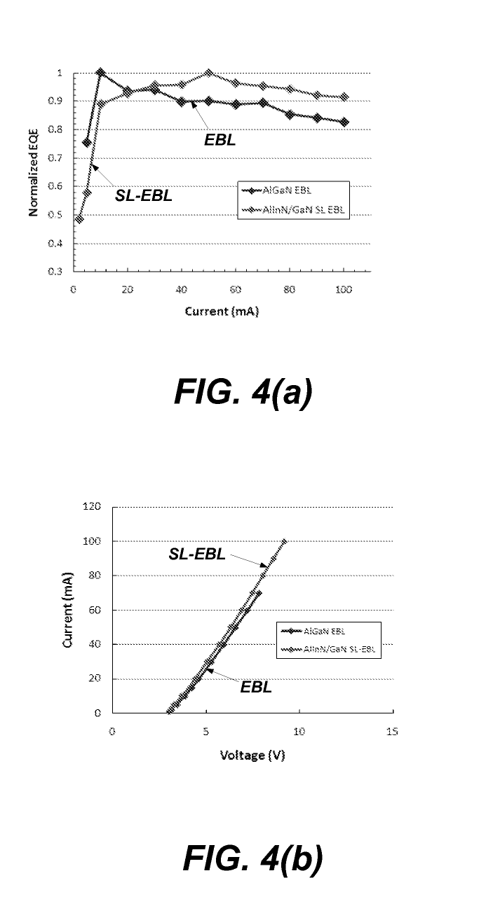

The external quantum efficiency (EQE) of SL-EBL LEDs has been measured under pulse conditions with a 10% duty cycle, as compared with AlGaN EBL LEDs with a peak wavelength around 413 nm. FIG. 4(a) is a graph illustrating the normalized EQE as a function of driving current and FIG. 4(b) is a graph illustrating the I-V characteristics for AlGaN EBL LEDs and AlInN/GaN SL-EBL LEDs. As the graphs of FIGS. 4(a) and 4(b) show, the efficiency droop is less for SL-EBL LEDs. Similar operating voltage and the series resistance between these two LEDs suggest that Mg-doping of AlInN/GaN SL-EBL at least as efficient as it is in AlGaN.

Nomenclature

The terms “nitride,” “III-nitride,” or “Group-III nitride”, as used herein refer to any alloy composition of the (Al,Ga,In)N semiconductors having the formula AlₓGa_{y}In_{z}N where 0≦x≦1, 0≦y≦1, and 0≦z≦1. These terms are intended to be broadly construed to include respective nitrides of the single species, Al, Ga, and In, as well as binary and ternary compositions of such Group III metal species. Accordingly, it will be appreciated that the discussion of the invention hereinafter in reference to GaN and InGaN materials is applicable to the formation of various other (Al,Ga,In)N material species. Further, (Al,Ga,In)N materials within the scope of the invention may further include minor quantities of dopants and/or other impurity or inclusional materials.

### REFERENCES

The following references are incorporated by reference herein.
[1] S. Nakamura, M. Senoh, N. Iwasa, S. Nagahama, T. Yamada, and T. Mukai, Jpn. J. Appl. Phys. 34, L1332 (1995).
[2] J. Piprek, Phys. Status Solidi A 207, 2217 (2010).
[3] S. C. Choi, H. J. Kim, S. Kim, J. Liu, J. Kim, J. Ryou, R. D. Dupuis, A. M. Fischer, and F. A. Ponce, Appl. Phys. Lett. 96, 221105 (2010).
[4] R. Butté, J.-F. Carlin, E. Feltin, M. Gonschorek, S. Nicolay, G. Christmann, D. Simeonov, A. Castiglia, J. Dorsaz, H. J. Buehlmann, S. Christopoulos, G. B. H. V. Hög, A. J. D. Grundy, M. Mosca, C. Pinquier, M. A. Py, F. Demangeot, J. Frandon, P. G. Lagoudakis, J. J. Baumberg, and N. Grandjean, J. Phys. D: Appl. Phys. 40, 6328 (2007).
[5] M. Akazawa, T. Matsuyama, T. Hashizume, M. Hiroki, S. Yamahata, and N. Shigekawa, Appl. Phys. Lett. 96, 132104 (2010).
[6] A. T. Cheng, Y. K. Su, and W. C. Lai, Phys. Status Solidi C 5, 1685 (2008).
[7] Z. T. Chen, S. X. Tan, Y. Sakai, and T. Egawa, Appl. Phys. Lett. 94, 213504 (2009).

### CONCLUSION

This concludes the description of the preferred embodiments of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An optoelectronic device, comprising:
a III-nitride active region for emitting light; and
a III-nitride superlattice structure formed near the III-nitride active region and having:
a first layer including at least Al and In; and
a second layer including at least Ga;
wherein the III-nitride superlattice structure comprises an electron blocking layer, and
wherein the optoelectronic device has a reduced droop as compared to an optoelectronic device without the III-nitride superlattice structure.

2. The device of claim 1, wherein the first layer is closely lattice matched to the second layer.

3. The device of claim 1, wherein the first layer is closely lattice matched to an underlying epitaxial layer.

4. The device of claim 1, wherein the first layer is AlₓIn₁₋ₓN and the second layer is GaN, In_{y}Ga_{1-y}N, or Al_{z}Ga_{1-z}N.

5. The device of claim 4, wherein the first layer is AlₓIn₁₋ₓN where 0.77≦x≦0.85.

6. The device of claim 1, wherein the first layer is Mg doped.

7. The device of claim 1, wherein the second layer is Mg doped.

8. The device of claim 1, wherein the first layer has a thickness of about 1 nm to about 5 nm.

9. The device of claim 1, wherein the second layer has a thickness of about 1 nm to about 5 nm.

10. The device of claim 1, wherein the superlattice structure has a thickness of about 20 nm to about 50 nm.

11. A method of fabricating an optoelectronic device, comprising:
forming a III-nitride active region for emitting light; and
forming a III-nitride superlattice structure near the III-nitride active region having:
a first layer including at least Al and In; and
a second layer including at least Ga;
wherein the III-nitride superlattice structure comprises an electron blocking layer, and
wherein the optoelectronic device has an reduced droop as compared to an optoelectronic device without the III-nitride superlattice structure.

12. The method of claim 11, wherein the first layer is closely lattice matched to the second layer.

13. The method of claim 11, wherein the first layer is closely lattice matched to an underlying epitaxial layer.

14. The method of claim 11, wherein the first layer is AlₓIn₁₋ₓN and the second layer is GaN, In_{y}Ga_{1-y}N, or Al_{z}Ga_{1-z}N.

15. The method of claim 14, wherein the first layer is AlₓIn₁₋ₓN where 0.77≦x≦0.85.

16. The method of claim 11, wherein the first layer is Mg doped.

17. The method of claim 11, wherein the second layer is Mg doped.

18. The method of claim 11, wherein the first layer has a thickness of about 1 nm to about 5 nm.

19. The method of claim 11, wherein the second layer has a thickness of about 1 nm to about 5 nm.

20. The method of claim 11, wherein the superlattice structure has a thickness of about 20 nm to about 50 nm.

21. A device fabricated using the method of claim 11.
